(19) United States
(12) Patent Application Publication
(10) Pub. No.: US 2026/0366416 A1
(43) Pub. Date: Nov. 19, 2026

(54) METHOD AND SYSTEM FOR PREDICTING PRODUCTIVITY OF SHALE OIL AND GAS WELLS

(71) Applicant: JPMorgan Chase Bank, N.A., New York, NY (US)

(72) Inventors: Mark L DEVERKA, Houston, TX (US); Jonathan L SLOAN, Houston, TX (US); Taylor A HART, Houston, TX (US); Mayank KUMAR, Mumbai (IN); Promel JAIN, Thane (IN)

(73) Assignee: JPMorgan Chase Bank, N.A., New York, NY (US)

(21) Appl. No.: 19/251,443

(22) Filed: Jun. 26, 2025

(30) Foreign Application Priority Data
May 14, 2025 (IN) 202511046319

(51) Int. Cl. E21B 47/00; G06F 30/27

(52) U.S. Cl. CPC E21B 47/00; G06F 30/27; E21B 2200/20

(57) ABSTRACT

Various methods and processes, apparatuses or systems, and media for predicting productivity of shale oil and gas wells in order to enhance accuracy of asset valuation and advisory services are disclosed. The method includes: training a first machine learning (ML) model using first historical data that relates to a productivity of s shale oil well; receiving first information that relates to the shale oil well; providing a subset of the first information as an input to the first ML model; and generating, by using the first ML model, a first prediction that relates to a productivity of the shale oil well over a predetermined time interval.

### CROSS-REFERENCE TO RELATED APPLICATIONS

This application claims priority benefit from Indian Application No. 202511046319, filed May 14, 2025 in the Indian Patent Office, which is hereby incorporated by reference in its entirety.

### TECHNICAL FIELD

This disclosure relates to methods and apparatuses for predicting productivity of shale oil and gas wells in order to enhance accuracy of asset valuation and advisory services to oil and gas companies and other interested entities.

### BACKGROUND

The developments described in this section are known to the inventors. However, unless otherwise indicated, it should not be assumed that any of the developments described in this section qualify as prior art merely by virtue of their inclusion in this section, or that these developments are known to a person of ordinary skill in the art.

There are significant challenges faced by the North American shale industry in accurately projecting the future performance of individual wells, fields, assets, and basins. These challenges have given rise to corresponding challenges in accurately predicting the valuation of these assets.

Conventional methods often struggle to integrate the complex interplay of geological, engineering, and technical parameters that influence well performance. This lack of precision can lead to suboptimal asset valuations, strategic decisions, and risk assessments.

The need for precise forecasts is critical for making informed strategic, corporate, financial, and transaction decisions. Accordingly, there is a need for a mechanism for predicting productivity of shale oil and gas wells in order to enhance accuracy of asset valuation and advisory services to oil and gas companies and other interested entities.

### SUMMARY

The present disclosure, through one or more of its various aspects, embodiments, and/or specific features or sub-components, provides, among other features, various systems, servers, devices, methods, media, programs, and platforms for predicting productivity of shale oil and gas wells in order to enhance accuracy of asset valuation and advisory services.

According to an aspect of the present disclosure, a method for predicting a productivity of a shale oil well is provided. The method may be implemented by at least one processor. The method may include: training a first machine learning (ML) model using first historical data that relates to a productivity of the shale oil well; receiving first information that relates to the shale oil well; providing a subset of the first information as an input to the first ML model; and generating, by using the first ML model, a first prediction that relates to a productivity of the shale oil well over a predetermined time interval.

The predetermined time interval may include at least one from among a three-month interval, a six-month interval, and a twelve-month interval.

The first information may include: distance information that indicates a distance between the shale oil well and a focus well that corresponds to the shale oil well; and age information that relates to an age difference between the shale oil well and the focus well. The method may further include using the distance information and the age information to determine whether the shale oil well is a parent well or a proximity well, and including a result of the determination of whether the shale oil well is the parent well or the proximity well in the subset of the first information that is provided as the input to the first ML model.

The method may further include: calculating each of a horizonal distance, a vertical distance, and a tangential distance between the shale oil well and a nearest different shale oil well; and including each of the calculated horizontal distance, the calculated vertical distance, and the calculated tangential distance in the subset of the first information that is provided as the input to the first ML model.

The first prediction may include second information that relates to an expected cumulative production of the shale oil well over the predetermined time interval and third information that relates to an expected normalized production of the shale oil well over the predetermined time interval.

The first information may include information that relates to at least one geological feature of the shale oil well, information that relates to at least one operational feature of the shale oil well, and information that relates to at least one production feature of the shale oil well.

The method may further include using a result of the generating of the first prediction to determine at least one model performance metric from among an R-squared mean square error (MSE) metric and a mean absolute error (MAE) metric.

The method may further include performing, based on the first prediction, a feature importance analysis by using SHapley Additive exPlanations (SHAP) values to analyze a relative respective importance of each of a plurality of individual features in order to determine a corresponding effect on the productivity of the shale oil well.

According to another embodiment, a computing apparatus for predicting a productivity of a shale oil well is provided. The computing apparatus includes a processor; a memory; and a communication interface coupled to each of the processor and the memory. The processor may be configured to: train a first ML model using first historical data that relates to a productivity of the shale oil well; receive, via the communication interface, first information that relates to the shale oil well; provide a subset of the first information as an input to the first ML model; and generate, by using the first ML model, a first prediction that relates to a productivity of the shale oil well over a predetermined time interval.

The predetermined time interval may include at least one from among a three-month interval, a six-month interval, and a twelve-month interval.

The first information may include: distance information that indicates a distance between the shale oil well and a focus well that corresponds to the shale oil well; and age information that relates to an age difference between the shale oil well and the focus well. The processor may be further configured to use the distance information and the age information to determine whether the shale oil well is a parent well or a proximity well, and to include a result of the determination of whether the shale oil well is the parent well or the proximity well in the subset of the first information that is provided as the input to the first ML model.

The processor may be further configured to: calculate each of a horizonal distance, a vertical distance, and a tangential distance between the shale oil well and a nearest different shale oil well; and include each of the calculated horizontal distance, the calculated vertical distance, and the calculated tangential distance in the subset of the first information that is provided as the input to the first ML model.

The first prediction may include second information that relates to an expected cumulative production of the shale oil well over the predetermined time interval and third information that relates to an expected normalized production of the shale oil well over the predetermined time interval.

The first information may include information that relates to at least one geological feature of the shale oil well, information that relates to at least one operational feature of the shale oil well, and information that relates to at least one production feature of the shale oil well.

The processor may be further configured to use the first prediction to determine at least one model performance metric from among an R-squared mean square error (MSE) metric and a mean absolute error (MAE) metric.

The processor may be further configured to perform, based on the first prediction, a feature importance analysis by using SHapley Additive exPlanations (SHAP) values to analyze a relative respective importance of each of a plurality of individual features in order to determine a corresponding effect on the productivity of the shale oil well.

According to yet another embodiment, a non-transitory computer readable storage medium storing instructions for predicting a productivity of a shale oil well is provided. The storage medium includes a set of executable code which, when executed by a processor, causes the processor to: train a first ML model using first historical data that relates to a productivity of the shale oil well; receive first information that relates to the shale oil well; provide a subset of the first information as an input to the first ML model; and generate, by using the first ML model, a first prediction that relates to a productivity of the shale oil well over a predetermined time interval.

The predetermined time interval may include at least one from among a three-month interval, a six-month interval, and a twelve-month interval.

The first information may include: distance information that indicates a distance between the shale oil well and a focus well that corresponds to the shale oil well; and age information that relates to an age difference between the shale oil well and the focus well. When executed, the executable code may further cause the processor to use the distance information and the age information to determine whether the shale oil well is a parent well or a proximity well, and to include a result of the determination of whether the shale oil well is the parent well or the proximity well in the subset of the first information that is provided as the input to the first ML model.

When executed, the executable code may further cause the processor to: calculate each of a horizonal distance, a vertical distance, and a tangential distance between the shale oil well and a nearest different shale oil well; and include each of the calculated horizontal distance, the calculated vertical distance, and the calculated tangential distance in the subset of the first information that is provided as the input to the first ML model.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a computer system for implementing a method for predicting productivity of shale oil and gas wells in order to enhance accuracy of asset valuation and advisory services, in accordance with an embodiment.

FIG. 2 illustrates an exemplary diagram of a network environment with a device for predicting productivity of shale oil and gas wells in order to enhance accuracy of asset valuation and advisory services, in accordance with an embodiment.

FIG. 3 illustrates a system diagram for implementing a method for predicting productivity of shale oil and gas wells in order to enhance accuracy of asset valuation and advisory services, in accordance with an embodiment.

FIG. 4 illustrates an exemplary flow chart of a process for predicting productivity of shale oil and gas wells in order to enhance accuracy of asset valuation and advisory services, in accordance with an embodiment.

### DETAILED DESCRIPTION

Methods and apparatuses for predicting productivity of shale oil and gas wells in order to enhance accuracy of asset valuation and advisory services to oil and gas companies and other interested entities are provided. In an embodiment, the present inventive concept employs advanced machine learning algorithms to efficiently process and analyze vast amounts of data from shale oil and gas wells. This capability is crucial for managing extensive well portfolios and dealing with continuous data influx. In this aspect, traditional manual methods are impractical for handling such large datasets due to their volume and complexity.

In an embodiment, the machine learning model analyzes multi-dimensional data sets, encompassing geological, operational, and production variables. This comprehensive analysis captures complex relationships and interactions affecting well productivity. By considering multiple dimensions simultaneously, the model provides a holistic and accurate understanding of well performance, surpassing the capabilities of traditional statistical methods.

In an embodiment, sophisticated algorithms, such as random forest regression, enable the model to achieve high accuracy in predictions by handling non-linear relationships within the data. Traditional methods often rely on averaging data from multiple wells, which blends all factors affecting productivity. These averages are highly susceptible to outliers and the selection of well data, leading to potential inaccuracies. In addition, the model processes data rapidly, allowing for real-time or near-real-time analysis and decision-making, providing timely insights for optimizing well operations

Conventional manual analysis of complex and voluminous data is time-consuming, resource-intensive, and prone to human error. In an embodiment, the present inventive concept automates the analysis process, thereby ensuring consistent and reliable results. In addition, the machine learning model identifies subtle patterns and trends within the data that may not be apparent through manual analysis, enabling more informed decision-making and optimized well performance.

Traditional methods lack the ability to perform sensitivity analyses on individual controllable parameters, making it difficult to understand the impact of specific variables on productivity. In an embodiment, the machine learning model simulates “what-if” scenarios by adjusting parameters and predicting changes in productivity, thereby allowing operators to explore operational strategies and make data-driven decisions. The ability to conduct sensitivity analyses and “what-if” scenarios also empowers operators to anticipate the effects of changes in operational parameters, leading to more informed and strategic decision-making. This capability results in improved well performance, reduced operational risks, and increased efficiency, enhancing the overall value of the asset.

Through one or more of its various aspects, embodiments and/or specific features or sub-components of the present disclosure, are intended to bring out one or more of the advantages as specifically described above and noted below.

The examples may also be embodied as one or more non-transitory computer readable media having instructions stored thereon for one or more aspects of the present technology as described and illustrated by way of the examples herein. The instructions in some examples include executable code that, when executed by one or more processors, cause the processors to carry out steps necessary to implement the methods of the examples of this technology that are described and illustrated herein.

As is traditional in the field of the present disclosure, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the example embodiments may be physically separated into two or more interacting and discrete blocks, units and/or modules without departing from the scope of the inventive concepts. Further, the blocks, units and/or modules of the example embodiments may be physically combined into more complex blocks, units and/or modules without departing from the scope of the present disclosure.

As disclosed herein, a system or method for predicting productivity of shale oil and gas wells in order to enhance accuracy of asset valuation and advisory services may optimize asset valuations, strategic decisions, and risk assessments to by using artificial intelligence (AI) to integrate the complex interplay of geological, engineering, and technical parameters that influence well performance. In particular, the system or method may achieve these improvements by: training a first AI model using first historical data that relates to a productivity of the shale oil well; receiving first information that relates to the shale oil well; providing a subset of the first information as an input to the first AI model; and generating, by using the first AI model, a first prediction that relates to a productivity of the shale oil well over a predetermined time interval.

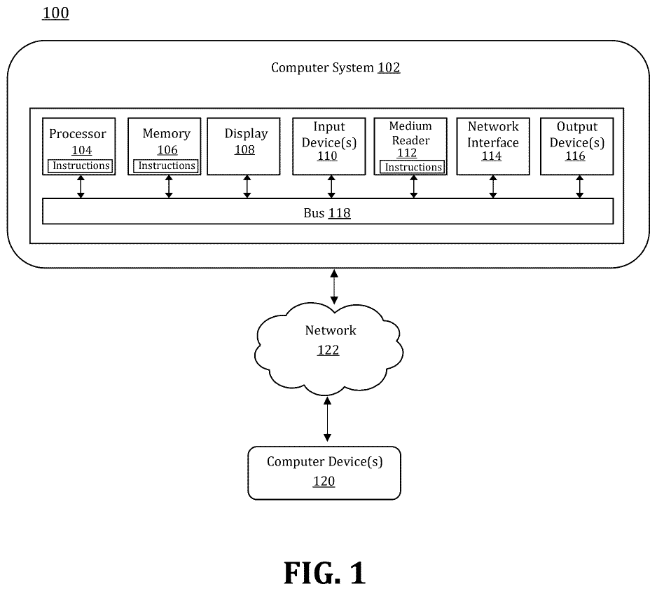

FIG. 1 is an exemplary system 100 for use in implementing a method for predicting productivity of shale oil and gas wells in order to enhance accuracy of asset valuation and advisory services, in accordance with an embodiment. The system 100 is generally shown and may include a computer system 102, which is generally indicated.

The computer system 102 may include a set of instructions that may be executed to cause the computer system 102 to perform any one or more of the methods or computer-based functions disclosed herein, either alone or in combination with the other described devices. The computer system 102 may operate as a standalone device or may be connected to other systems or peripheral devices. For example, the computer system 102 may include, or be included within, any one or more computers, servers, systems, communication networks or cloud environment. Even further, the instructions may be operative in such a cloud-based computing environment.

In a networked deployment, the computer system 102 may operate in the capacity of a server or as a client user computer in a server-client user network environment, a client user computer in a cloud computing environment, or as a peer computer system in a peer-to-peer (or distributed) network environment. The computer system 102, or portions thereof, may be implemented as, or incorporated into, various devices, such as a personal computer, a tablet computer, a set-top box, a personal digital assistant, a mobile device, a palmtop computer, a laptop computer, a desktop computer, a communications device, a wireless smart phone, a personal trusted device, a wearable device, a global positioning satellite (GPS) device, a web appliance, or any other machine capable of executing a set of instructions (sequential or otherwise) that specify actions to be taken by that machine. Further, while a single computer system 102 is illustrated, additional embodiments may include any collection of systems or sub-systems that individually or jointly execute instructions or perform functions. The term system shall be taken throughout the present disclosure to include any collection of systems or sub-systems that individually or jointly execute a set, or multiple sets, of instructions to perform one or more computer functions.

As illustrated in FIG. 1, the computer system 102 may include at least one processor 104. The processor 104 is tangible and non-transitory. As used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The processor 104 is an article of manufacture and/or a machine component. The processor 104 is configured to execute software instructions in order to perform functions as described in the various embodiments herein. The processor 104 may be a general-purpose processor or may be part of an application specific integrated circuit (ASIC). The processor 104 may also be a microprocessor, a microcomputer, a processor chip, a controller, a microcontroller, a digital signal processor (DSP), a state machine, or a programmable logic device. The processor 104 may also be a logical circuit, including a programmable gate array (PGA) such as a field programmable gate array (FPGA), or another type of circuit that includes discrete gate and/or transistor logic. The processor 104 may be a central processing unit (CPU), a graphics processing unit (GPU), or both. Additionally, any processor described herein may include multiple processors, parallel processors, or both. Multiple processors may be included in, or coupled to, a single device or multiple devices.

The computer system 102 may also include a computer memory 106. The computer memory 106 may include a static memory, a dynamic memory, or both in communication. Memories described herein are tangible storage mediums that can store data and executable instructions, and are non-transitory during the time instructions are stored therein. Again, as used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The memories are an article of manufacture and/or machine component. Memories described herein are computer-readable mediums from which data and executable instructions may be read by a computer. Memories as described herein may be random access memory (RAM), read only memory (ROM), flash memory, electrically programmable read only memory (EPROM), electrically erasable programmable read-only memory (EEPROM), registers, a hard disk, a cache, a removable disk, tape, compact disk read only memory (CD-ROM), digital versatile disk (DVD), floppy disk, or any other form of storage medium known in the art. Memories may be volatile or non-volatile, secure and/or encrypted, unsecure and/or unencrypted. Of course, the computer memory 106 may comprise any combination of memories or a single storage.

The computer system 102 may further include a display 108, such as a liquid crystal display (LCD), an organic light emitting diode (OLED), a flat panel display, a solid-state display, a cathode ray tube (CRT), a plasma display, or any other known display.

The computer system 102 may also include at least one input device 110, such as a keyboard, a touch-sensitive input screen or pad, a speech input, a mouse, a remote control device having a wireless keypad, a microphone coupled to a speech recognition engine, a camera such as a video camera or still camera, a cursor control device, a GPS device, a visual positioning system (VPS) device, an altimeter, a gyroscope, an accelerometer, a proximity sensor, or any combination thereof. Those skilled in the art appreciate that various embodiments of the computer system 102 may include multiple input devices 110. Moreover, those skilled in the art further appreciate that the above-listed, exemplary input devices 110 are not meant to be exhaustive and that the computer system 102 may include any additional, or alternative, input devices 110.

The computer system 102 may also include a medium reader 112 which is configured to read any one or more sets of instructions, e.g., software, from any of the memories described herein. The instructions, when executed by a processor, may be used to perform one or more of the methods and processes as described herein. In a particular embodiment, the instructions may reside completely, or at least partially, within the memory 106, the medium reader 112, and/or the processor 104 during execution by the computer system 102.

Furthermore, the computer system 102 may include any additional devices, components, parts, peripherals, hardware, software, or any combination thereof which are commonly known and understood as being included with or within a computer system, such as, but not limited to, a network interface 114 and an output device 116. The output device 116 may be, but is not limited to, a speaker, an audio out, a video out, a remote control output, a printer, or any combination thereof.

Each of the components of the computer system 102 may be interconnected and communicate via a bus 118 or other communication link. As shown in FIG. 1, the components may each be interconnected and communicate via an internal bus. However, those skilled in the art appreciate that any of the components may also be connected via an expansion bus. Moreover, the bus 118 may enable communication via any standard or other specification commonly known and understood such as, but not limited to, peripheral component interconnect, peripheral component interconnect express, parallel advanced technology attachment, serial advanced technology attachment, etc.

The computer system 102 may be in communication with one or more additional computer devices 120 via a network 122. The network 122 may be, but is not limited to, a local area network, a wide area network, the Internet, a telephony network, a short-range network, or any other network commonly known and understood in the art. The short-range network may include, for example, infrared, near field communication, ultraband, or any combination thereof. Those skilled in the art appreciate that additional networks 122 which are known and understood may additionally or alternatively be used and that the exemplary networks 122 are not limiting or exhaustive. Also, while the network 122 is shown in FIG. 1 as a wireless network, those skilled in the art appreciate that the network 122 may also be a wired network.

The additional computer device 120 is shown in FIG. 1 as a personal computer. However, those skilled in the art appreciate that, in alternative embodiments of the present application, the computer device 120 may be a laptop computer, a tablet PC, a personal digital assistant, a mobile device, a palmtop computer, a desktop computer, a communications device, a wireless telephone, a personal trusted device, a web appliance, a server, or any other device that is capable of executing a set of instructions, sequential or otherwise, that specify actions to be taken by that device. Of course, those skilled in the art appreciate that the above-listed devices are merely exemplary devices and that the device 120 may be any additional device or apparatus commonly known and understood in the art without departing from the scope of the present application. For example, the computer device 120 may be the same or similar to the computer system 102. Furthermore, those skilled in the art similarly understand that the device may be any combination of devices and apparatuses.

Of course, those skilled in the art appreciate that the above-listed components of the computer system 102 are merely meant to be exemplary and are not intended to be exhaustive and/or inclusive. Furthermore, the examples of the components listed above are also meant to be exemplary and similarly are not meant to be exhaustive and/or inclusive.

In some embodiments, the modules implemented by the system 100 may be platform, language, database, and cloud agnostic that may allow for consistent easy orchestration and passing of data through various components to output a desired result regardless of platform, browser, language, database, and cloud environment by writing programs accordingly. The configuration or data files, in some embodiments, may be written using JavaScript Object Notation (JSON), but the disclosure is not limited thereto. For example, the configuration or data files may easily be extended to other readable file formats such as Extensible Markup Language (XML), YAML Ain't Markup Language (YAML), etc., or any other configuration-based languages.

In accordance with various embodiments of the present disclosure, the methods described herein may be implemented using a hardware computer system that executes software programs. Further, in a non-limited embodiment, implementations can include distributed processing, component/object distributed processing, and an operation mode having parallel processing capabilities. Virtual computer system processing may be constructed to implement one or more of the methods or functionality as described herein, and a processor described herein may be used to support a virtual processing environment.

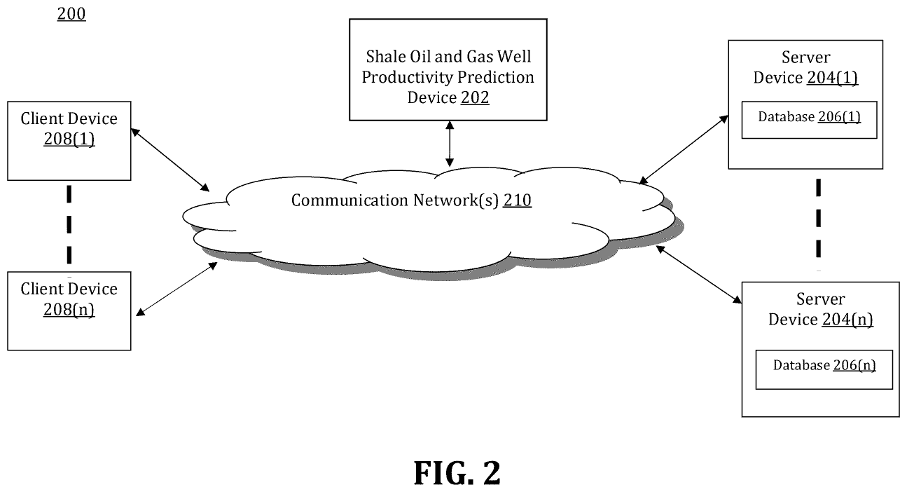

Referring to FIG. 2, a schematic of an exemplary network environment 200 for implementing a shale oil and gas well productivity prediction device (SOGWPPD) of the instant disclosure is illustrated.

In some embodiments, the above-described problems associated with conventional tools may be overcome by implementing a SOGWPPD 202 as illustrated in FIG. 2 that may be configured for implementing a method for predicting productivity of shale oil and gas wells in order to enhance accuracy of asset valuation and advisory services, but the disclosure is not limited thereto.

The SOGWPPD 202 may have one or more computer system 102s, as described with respect to FIG. 1, which in aggregate provide the necessary functions.

The SOGWPPD 202 may store one or more applications that can include executable instructions that, when executed by the SOGWPPD 202, cause the SOGWPPD 202 to perform actions, such as to transmit, receive, or otherwise process network messages, for example, and to perform other actions described and illustrated below with reference to the figures. The application(s) may be implemented as modules or components of other applications. Further, the application(s) may be implemented as operating system extensions, modules, plugins, or the like.

Even further, the application(s) may be operative in a cloud-based computing environment. The application(s) may be executed within or as virtual machine(s) or virtual server(s) that may be managed in a cloud-based computing environment. Also, the application(s), and even the SOGWPPD 202 itself, may be located in virtual server(s) running in a cloud-based computing environment rather than being tied to one or more specific physical network computing devices. Also, the application(s) may be running in one or more virtual machines (VMs) executing on the SOGWPPD 202. Additionally, in one or more embodiments of this technology, virtual machine(s) running on the SOGWPPD 202 may be managed or supervised by a hypervisor.

In the network environment 200 of FIG. 2, the SOGWPPD 202 is coupled to a plurality of server devices 204(1)-204(n) that hosts a plurality of databases 206(1)-206(n), and also to a plurality of client devices 208(1)-208(n) via communication network(s) 210. A communication interface of the SOGWPPD 202, such as the network interface 114 of the computer system 102 of FIG. 1, operatively couples and communicates between the SOGWPPD 202, the server devices 204(1)-204(n), and/or the client devices 208(1)-208(n), which are all coupled together by the communication network(s) 210, although other types and/or numbers of communication networks or systems with other types and/or numbers of connections and/or configurations to other devices and/or elements may also be used.

The communication network(s) 210 may be the same or similar to the network 122 as described with respect to FIG. 1, although the SOGWPPD 202, the server devices 204(1)-204(n), and/or the client devices 208(1)-208(n) may be coupled together via other topologies. Additionally, the network environment 200 may include other network devices such as one or more routers and/or switches, for example, which are well known in the art and thus will not be described herein.

By way of example only, the communication network(s) 210 may include local area network(s) (LAN(s)) or wide area network(s) (WAN(s)), and can use TCP/IP over Ethernet and industry-standard protocols, although other types and/or numbers of protocols and/or communication networks may be used. The communication network(s) 210 in this example may employ any suitable interface mechanisms and network communication technologies including, for example, teletraffic in any suitable form (e.g., voice, modem, and the like), Public Switched Telephone Network (PSTNs), Ethernet-based Packet Data Networks (PDNs), combinations thereof, and the like.

The SOGWPPD 202 may be a standalone device or integrated with one or more other devices or apparatuses, such as one or more of the server devices 204(1)-204(n), for example. In one particular example, the SOGWPPD 202 may be hosted by one of the server devices 204(1)-204(n), and other arrangements are also possible. Moreover, one or more of the devices of the SOGWPPD 202 may be in the same or a different communication network including one or more public, private, or cloud networks, for example.

The plurality of server devices 204(1)-204(n) may be the same or similar to the computer system 102 or the computer device 120 as described with respect to FIG. 1, including any features or combination of features described with respect thereto. For example, any of the server devices 204(1)-204(n) may include, among other features, one or more processors, a memory, and a communication interface, which are coupled together by a bus or other communication link, although other numbers and/or types of network devices may be used. The server devices 204(1)-204(n) in this example may process requests received from the SOGWPPD 202 via the communication network(s) 210 according to the HyperText Transfer Protocol (HTTP)-based and/or JSON protocol, for example, although other protocols may also be used.

The server devices 204(1)-204(n) may be hardware or software or may represent a system with multiple servers in a pool, which may include internal or external networks. The server devices 204(1)-204(n) hosts the databases 206(1)-206(n) that are configured to store various types of data.

Although the server devices 204(1)-204(n) are illustrated as single devices, one or more actions of each of the server devices 204(1)-204(n) may be distributed across one or more distinct network computing devices that together comprise one or more of the server devices 204(1)-204(n). Moreover, the server devices 204(1)-204(n) are not limited to a particular configuration. Thus, the server devices 204(1)-204(n) may contain a plurality of network computing devices that operate using a master/slave approach, whereby one of the network computing devices of the server devices 204(1)-204(n) operates to manage and/or otherwise coordinate operations of the other network computing devices.

The server devices 204(1)-204(n) may operate as a plurality of network computing devices within a cluster architecture, a peer-to peer architecture, virtual machines, or within a cloud architecture, for example. Thus, the technology disclosed herein is not to be construed as being limited to a single environment and other configurations and architectures are also envisaged.

The plurality of client devices 208(1)-208(n) may also be the same or similar to the computer system 102 or the computer device 120 as described with respect to FIG. 1, including any features or combination of features described with respect thereto. Client device in this context refers to any computing device that interfaces to communications network(s) 210 to obtain resources from one or more server devices 204(1)-204(n) or other client devices 208(1)-208(n).

In some embodiments, the client devices 208(1)-208(n) in this example may include any type of computing device that can facilitate the implementation of the SOGWPPD 202 that may efficiently provide a platform for implementing a method for predicting productivity of shale oil and gas wells in order to enhance accuracy of asset valuation and advisory services, but the disclosure is not limited thereto.

The client devices 208(1)-208(n) may run interface applications, such as standard web browsers or standalone client applications, which may provide an interface to communicate with the SOGWPPD 202 via the communication network(s) 210 in order to communicate user requests. The client devices 208(1)-208(n) may further include, among other features, a display device, such as a display screen or touchscreen, and/or an input device, such as a keyboard, for example.

Although the exemplary network environment 200 with the SOGWPPD 202, the server devices 204(1)-204(n), the client devices 208(1)-208(n), and the communication network(s) 210 are described and illustrated herein, other types and/or numbers of systems, devices, components, and/or elements in other topologies may be used. It is to be understood that the systems of the examples described herein are for exemplary purposes, as many variations of the specific hardware and software used to implement the examples are possible, as may be appreciated by those skilled in the relevant art(s).

One or more of the devices depicted in the network environment 200, such as the SOGWPPD 202, the server devices 204(1)-204(n), or the client devices 208(1)-208(n), for example, may be configured to operate as virtual instances on the same physical machine. For example, one or more of the SOGWPPD 202, the server devices 204(1)-204(n), or the client devices 208(1)-208(n) may operate on the same physical device rather than as separate devices communicating through communication network(s) 210. Additionally, there may be more or fewer SOGWPPDs 202, server devices 204(1)-204(n), or client devices 208(1)-208(n) than illustrated in FIG. 2. In some embodiments, the SOGWPPD 202 may be configured to send code at run-time to remote server devices 204(1)-204(n), but the disclosure is not limited thereto.

In addition, two or more computing systems or devices may be substituted for any one of the systems or devices in any example. Accordingly, principles and advantages of distributed processing, such as redundancy and replication also may be implemented, as desired, to increase the robustness and performance of the devices and systems of the examples. The examples may also be implemented on computer system(s) that extend across any suitable network using any suitable interface mechanisms and traffic technologies, including by way of example only teletraffic in any suitable form (e.g., voice and modem), wireless traffic networks, cellular traffic networks, Packet Data Networks (PDNs), the Internet, intranets, and combinations thereof.

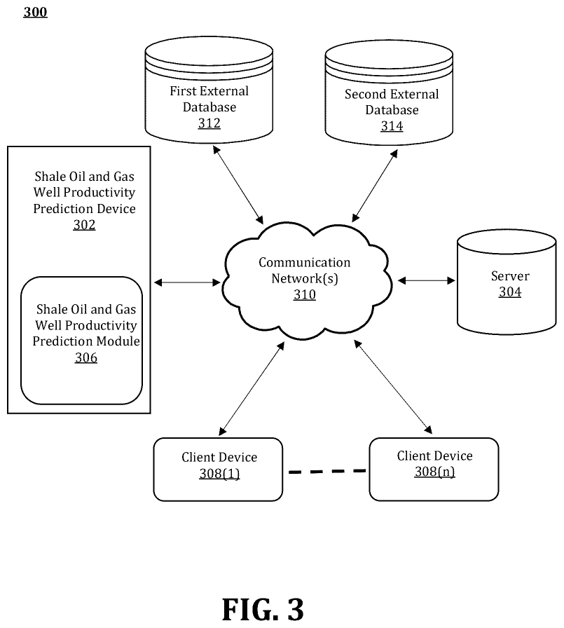

FIG. 3 illustrates a system diagram for implementing a SOGWPPD 302 having a shale oil and gas well productivity prediction module (SOGWPPM), in accordance with an embodiment.

As illustrated in FIG. 3, the system 300 may include a SOGWPPD 302 within which a SOGWPPM 306 is embedded, a server 304, a first external database 312, a second external database 314, a plurality of client devices 308(1) . . . 308(n), and a communication network 310.

In some embodiments, the SOGWPPD 302 including the SOGWPPM 306 may be connected to the server 304, and the database(s) 312 via the communication network 310. The SOGWPPD 302 may also be connected to the plurality of client devices 308(1) . . . 308(n) via the communication network 310, but the disclosure is not limited thereto.

In an embodiment, the SOGWPPD 302 is described and shown in FIG. 3 as including the SOGWPPM 306, although it may include other rules, policies, modules, databases, or applications, for example. In some embodiments, the first external database 312 and/or the second external database 314 may be configured to store ready to use modules written for each application programming interface (API) for all environments. Although only one database is illustrated in FIG. 3, the disclosure is not limited thereto. Any number of desired databases may be utilized for use in the disclosed invention herein. The databases 312, 314 may be a mainframe database, a log database that may produce programming for searching, monitoring, and analyzing machine-generated data via a web interface, etc., but the disclosure is not limited thereto.

In some embodiments, the SOGWPPM 306 may be configured to receive real-time feed of data from the plurality of client devices 308(1) . . . 308(n) and secondary sources via the communication network 310.

As may be described below, the SOGWPPM 306 may be configured to: train a first ML model using first historical data that relates to a productivity of the shale oil well; receive first information that relates to the shale oil well; provide a subset of the first information as an input to the first ML model; and generate, by using the first ML model, a first prediction that relates to a productivity of the shale oil well over a predetermined time interval, but the disclosure is not limited thereto.

The plurality of client devices 308(1) . . . 308(n) are illustrated as being in communication with the SOGWPPD 302. In this regard, the plurality of client devices 308(1) . . . 308(n) may be “clients” (e.g., customers) of the SOGWPPD 302 and are described herein as such. Nevertheless, it is to be known and understood that the plurality of client devices 308(1) . . . 308(n) need not necessarily be “clients” of the SOGWPPD 302, or any entity described in association therewith herein. Any additional or alternative relationship may exist between either or both of the plurality of client devices 308(1) . . . 308(n) and the SOGWPPD 302, or no relationship may exist.

The first client device 308(1) may be, for example, a smart phone. Of course, the first client device 308(1) may be any additional device described herein. The second client device 308(n) may be, for example, a personal computer (PC). Of course, the second client device 308(n) may also be any additional device described herein. In some embodiments, the server 304 may be the same or equivalent to the server device 204 as illustrated in FIG. 2.

The process may be executed via the communication network 310, which may comprise plural networks as described above. For example, in an embodiment, one or more of the plurality of client devices 308(1) . . . 308(n) may communicate with the SOGWPPD 302 via broadband or cellular communication. Of course, these embodiments are merely exemplary and are not limiting or exhaustive.

The computing device 301 may be the same or similar to any one of the client devices 208(1)-208(n) as described with respect to FIG. 2, including any features or combination of features described with respect thereto. The SOGWPPD 302 may be the same or similar to the SOGWPPD 202 as described with respect to FIG. 2, including any features or combination of features described with respect thereto.

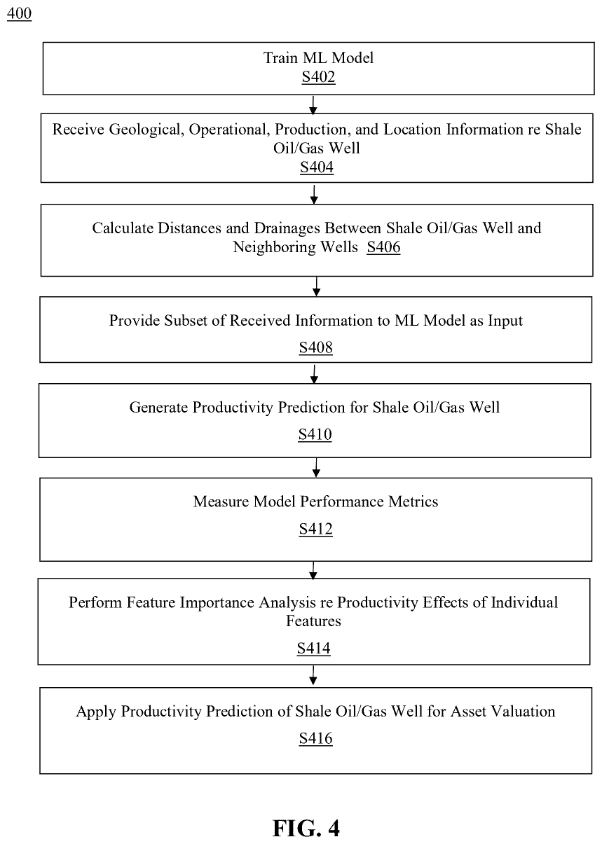

FIG. 4 illustrates an exemplary flow chart of a process 400 implemented by the SOGWPPM 306 of FIG. 3 for enablement of a system and a method for predicting productivity of shale oil and gas wells in order to enhance accuracy of asset valuation and advisory services, in accordance with an embodiment. It may be appreciated that the illustrated process 400 and associated steps may be performed in a different order, with illustrated steps omitted, with additional steps added, or with a combination of reordered, combined, omitted, or additional steps.

As illustrated in FIG. 4, at step S402, the process 400 may include training a first ML model using historical data that relates to a productivity of a shale oil well (or a shale gas well). For example, the historical data may include monthly production of oil and/or gas over a period of several months, such as, for example, a most recent six-month period, a most recent twelve-month period, a most recent five-year period, or any other suitable period of time. In an embodiment, the historical data may also include geological data that relates to the shale oil/gas well and/or engineering data that relates to the shale oil/gas well.

In an embodiment, the training of the ML model may be performed by randomly selecting 80% of the historical data to be used for training the ML model and then using the trained ML model to generate a prediction based on the remaining 20% of the historical data, also referred to as a “blind” set of data. This partitioning of the historical data may be done in order to check whether the ML model is properly tuned. In particular, because the 20% blind data set corresponds to actual historical production outputs, the prediction that is generated based on the 20% blind data set can be compared with the actual hard data to determine whether the ML model is accurately tuned for subsequent predictions of future production, and to thereby facilitate confident predictions.

At step S404, the process 400 may include receiving information that relates to the shale oil/gas well. In an embodiment, the information that relates to the shale oil/gas well may include information that relates to geological features of the shale oil well, information that relates to operational features of the shale oil/gas well, and information that relates to production features of the shale oil/gas well. For example, the geological features may include geological properties, such as a true vertical depth of the well, a clay volume of the well by percentage, an effective porosity of the well, a water saturation property of the well, and/or any other suitable type of geological property or feature. The operational features may include, for example, operational parameters such as a lateral length of the well, a proppant intensity parameter, and a fluid intensity parameter. The production features may include, for example, an average normalized liquids production value, a cumulative liquids production value a cumulative gas production value, a cumulative water production value, and monthly hydrocarbon volumes.

The information that relates to the shale oil/gas well may also include various other types of information, such as, for example, information about well locations. In an embodiment, the information about well locations may include distance information that indicates a distance between the shale oil/gas well and a focus well that corresponds to the shale oil/gas well. In an embodiment, the information that relates to the shale oil/gas well may also include age information that relates to an age difference between the shale oil/gas well and the focus well.

At step S406, the process 400 may include calculating distances and/or drainages between the shale oil/gas well and neighboring wells, such as, for example, a nearest different shale oil/gas well. The distances may include a horizontal distance, a vertical distance, and/or a tangential distance between the shale oil/gas well and any of the neighboring wells. Drainage information may be calculated by summing up cumulative production of proximity wells before a start date of the focus well. In an embodiment, the distance and the age difference between the shale oil/gas well and the corresponding focus well may be used to determine whether the shale oil/gas well is a parent well or a proximity well. In this aspect, a proximity well may be understood as being a well that falls within a predetermined radius of the focus well, such as, for example, 1800 feet, and also has been producing oil and/or gas for a minimum length of time, such as, for example, 180 days. A parent well may be understood as being a well within a larger radius of the focus well, such as, for example, 1.5 miles.

At step S408, the process 400 may include providing a subset of the information received in step S404 and the distance information calculated in step S406 to the trained first ML model as an input. Then, at step S410, the process may include using the first ML model to generate a prediction that relates to a productivity of the shale oil/gas well over a predetermined time interval. In an embodiment, the AI model may be configured to apply a random forest regression algorithm to the inputted information, in order to leverage the ability of this type of algorithm to handle complex and non-linear relationships in the data.

In an embodiment, the prediction may include information that relates to an expected cumulative production of the shale oil/gas well over the predetermined time interval and information that relates to an expected normalized production of the shale oil/gas well over the predetermined time interval. For example, the predetermined time interval may be equal to one month, three months, six months, twelve months, and/or any other suitable interval.

At step S412, the process 400 may include measuring one or more model performance metrics based on a result of the generation of the prediction. For example, an R-squared mean square error (MSE) metric may be measured. In this aspect, an R-squared MSE value that is greater than 0.8 may indicate a highly accurate fit of the AI model. As another example, a mean absolute error (MAE) metric may also be measured.

At step S414, the process 400 may include using the prediction generated in step S410 to perform a feature importance analysis that is designed to facilitate an understanding of the importance of individual well features to the productivity of the shale oil/gas well. In an embodiment, the feature importance analysis may be performed by using SHapley Additive exPlanations (SHAP) values to analyze a relative respective importance of each of a set of individual features, in order to determine a corresponding effect of the respective feature on well productivity.

At step S416, the process 400 may include applying the productivity prediction generated in step S410 for a purpose of asset valuation. In an embodiment, the asset valuation may include productivity prediction information that relates to the shale oil/gas well in conjunction with productivity prediction information that relate to other shale oil/gas wells, potentially including future shale oil/gas wells that do not exist presently but are projected to be constructed and utilized in the future.

In some embodiments as disclosed above in FIGS. 1-4, technical improvements effected by the instant disclosure may include a platform for implementing a shale oil and gas well productivity prediction management module configured for enablement of predicting productivity of shale oil and gas wells in order to enhance accuracy of asset valuation and advisory services, but the disclosure is not limited thereto.

Although the invention has been described with reference to several exemplary embodiments, it is understood that the words that have been used are words of description and illustration, rather than words of limitation. Changes may be made within the purview of the appended claims, as presently stated and as amended, without departing from the scope and spirit of the present disclosure in its aspects. Although the invention has been described with reference to particular means, materials and embodiments, the invention is not intended to be limited to the particulars disclosed; rather the invention extends to all functionally equivalent structures, methods, and uses such as are within the scope of the appended claims.

For example, while the computer-readable medium may be described as a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the embodiments disclosed herein.

The computer-readable medium may comprise a non-transitory computer-readable medium or media and/or comprise a transitory computer-readable medium or media. In a particular non-limiting, exemplary embodiment, the computer-readable medium can include a solid-state memory such as a memory card or other package that houses one or more non-volatile read-only memories. Further, the computer-readable medium may be a random access memory or other volatile re-writable memory. Additionally, the computer-readable medium can include a magneto-optical or optical medium, such as a disk or tapes or other storage device to capture carrier wave signals such as a signal communicated over a transmission medium. Accordingly, the disclosure is considered to include any computer-readable medium or other equivalents and successor media, in which data or instructions may be stored.

Although the present application describes specific embodiments which may be implemented as computer programs or code segments in computer-readable media, it is to be understood that dedicated hardware implementations, such as application specific integrated circuits, programmable logic arrays and other hardware devices, may be constructed to implement one or more of the embodiments described herein. Applications that may include the various embodiments set forth herein may broadly include a variety of electronic and computer systems. Accordingly, the present application may encompass software, firmware, and hardware implementations, or combinations thereof. Nothing in the present application should be interpreted as being implemented or implementable solely with software and not hardware.

Although the present specification describes components and functions that may be implemented in particular embodiments with reference to particular standards and protocols, the disclosure is not limited to such standards and protocols. Such standards are periodically superseded by faster or more efficient equivalents having essentially the same functions. Accordingly, replacement standards and protocols having the same or similar functions are considered equivalents thereof.

The illustrations of the embodiments described herein are intended to provide a general understanding of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, may be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for predicting a productivity of a shale oil well, the method being implemented by at least one processor, the method comprising:
training a first machine learning (ML) model using first historical data that relates to a productivity of the shale oil well;
receiving first information that relates to the shale oil well;
providing a subset of the first information as an input to the first ML model; and
generating, by using the first ML model, a first prediction that relates to a productivity of the shale oil well over a predetermined time interval.

2. The method of claim 1, wherein the predetermined time interval includes at least one from among a three-month interval, a six-month interval, and a twelve-month interval.

3. The method of claim 1, wherein the first information includes: distance information that indicates a distance between the shale oil well and a focus well that corresponds to the shale oil well; and age information that relates to an age difference between the shale oil well and the focus well, and
wherein the method further comprises using the distance information and the age information to determine whether the shale oil well is a parent well or a proximity well, and including a result of the determination of whether the shale oil well is the parent well or the proximity well in the subset of the first information that is provided as the input to the first ML model.

4. The method of claim 1, further comprising:
calculating each of a horizonal distance, a vertical distance, and a tangential distance between the shale oil well and a nearest different shale oil well; and
including each of the calculated horizontal distance, the calculated vertical distance, and the calculated tangential distance in the subset of the first information that is provided as the input to the first ML model.

5. The method of claim 1, wherein the first prediction includes second information that relates to an expected cumulative production of the shale oil well over the predetermined time interval and third information that relates to an expected normalized production of the shale oil well over the predetermined time interval.

6. The method of claim 1, wherein the first information includes information that relates to at least one geological feature of the shale oil well, information that relates to at least one operational feature of the shale oil well, and information that relates to at least one production feature of the shale oil well.

7. The method of claim 1, further comprising using a result of the generating of the first prediction to determine at least one model performance metric from among an R-squared mean square error (MSE) metric and a mean absolute error (MAE) metric.

8. The method of claim 1, further comprising performing, based on the first prediction, a feature importance analysis by using SHapley Additive exPlanations (SHAP) values to analyze a relative respective importance of each of a plurality of individual features in order to determine a corresponding effect on the productivity of the shale oil well.

9. A computing apparatus for predicting a productivity of a shale oil well, the computing apparatus comprising:
a processor;
a memory; and
a communication interface coupled to each of the processor and the memory,
wherein the processor is configured to:
train a first machine learning (ML) model using first historical data that relates to a productivity of the shale oil well;
receive, via the communication interface, first information that relates to the shale oil well;
provide a subset of the first information as an input to the first ML model; and
generate, by using the first ML model, a first prediction that relates to a productivity of the shale oil well over a predetermined time interval.

10. The computing apparatus of claim 9, wherein the predetermined time interval includes at least one from among a three-month interval, a six-month interval, and a twelve-month interval.

11. The computing apparatus of claim 9, wherein the first information includes:
distance information that indicates a distance between the shale oil well and a focus well that corresponds to the shale oil well; and age information that relates to an age difference between the shale oil well and the focus well, and
wherein the processor is further configured to use the distance information and the age information to determine whether the shale oil well is a parent well or a proximity well, and to include a result of the determination of whether the shale oil well is the parent well or the proximity well in the subset of the first information that is provided as the input to the first ML model.

12. The computing apparatus of claim 9, wherein the processor is further configured to:
calculate each of a horizonal distance, a vertical distance, and a tangential distance between the shale oil well and a nearest different shale oil well; and
include each of the calculated horizontal distance, the calculated vertical distance, and the calculated tangential distance in the subset of the first information that is provided as the input to the first ML model.

13. The computing apparatus of claim 9, wherein the first prediction includes second information that relates to an expected cumulative production of the shale oil well over the predetermined time interval and third information that relates to an expected normalized production of the shale oil well over the predetermined time interval.

14. The computing apparatus of claim 9, wherein the first information includes information that relates to at least one geological feature of the shale oil well, information that relates to at least one operational feature of the shale oil well, and information that relates to at least one production feature of the shale oil well.

15. The computing apparatus of claim 9, wherein the processor is further configured to use the first prediction to determine at least one model performance metric from among an R-squared mean square error (MSE) metric and a mean absolute error (MAE) metric.

16. The computing apparatus of claim 9, wherein the processor is further configured to perform, based on the first prediction, a feature importance analysis by using SHapley Additive exPlanations (SHAP) values to analyze a relative respective importance of each of a plurality of individual features in order to determine a corresponding effect on the productivity of the shale oil well.

17. A non-transitory computer readable storage medium storing instructions for predicting a productivity of a shale oil well, the storage medium comprising executable code which, when executed by a processor, causes the processor to:
train a first machine learning (ML) model using first historical data that relates to a productivity of the shale oil well;
receive first information that relates to the shale oil well;
provide a subset of the first information as an input to the first ML model; and
generate, by using the first ML model, a first prediction that relates to a productivity of the shale oil well over a predetermined time interval.

18. The storage medium of claim 17, wherein the predetermined time interval includes at least one from among a three-month interval, a six-month interval, and a twelve-month interval.

19. The storage medium of claim 17, wherein the first information includes: distance information that indicates a distance between the shale oil well and a focus well that corresponds to the shale oil well; and age information that relates to an age difference between the shale oil well and the focus well, and
wherein when executed, the executable code further causes the processor to use the distance information and the age information to determine whether the shale oil well is a parent well or a proximity well, and to include a result of the determination of whether the shale oil well is the parent well or the proximity well in the subset of the first information that is provided as the input to the first ML model.

20. The storage medium of claim 17, wherein when executed, the executable code further causes the processor to:
calculate each of a horizonal distance, a vertical distance, and a tangential distance between the shale oil well and a nearest different shale oil well; and
include each of the calculated horizontal distance, the calculated vertical distance, and the calculated tangential distance in the subset of the first information that is provided as the input to the first ML model.
